(19) United States
(12) Patent Application Publication
(10) Pub. No.: US 2022/0020830 A1
(43) Pub. Date: Jan. 20, 2022

(54) Patterning of Organic Light Emitting Diode Device and the OLED Displays Manufactured Therefrom

(71) Applicant: Dinguo CHEN, Taipei (TW)

(72) Inventors: Dinguo Chen, Taipei (TW); Xianglun Xu, Miaoli County (TW)

(21) Appl. No.: 17/309,277

(22) PCT Filed: Nov. 18, 2019
(86) PCT No.: PCT/CN2019/119228

§ 371 Date: May 14, 2021

Related U.S. Application Data
(60) Provisional application No. 62/768,983, filed on Nov. 19, 2018.
(60) Provisional application No. 62/768,987, filed on Nov. 19, 2018.

(51) Int. Cl. H01L 27/32; H01L 51/00; H01L 51/50; H01L 51/56

(52) U.S. Cl. CPC H01L 27/3246; H01L 27/322; H01L 51/0097; H01L 51/0018; G03F 7/094; H01L 51/56; H01L 2227/323; H01L 2251/5338; H01L 51/504

(57) ABSTRACT

A method for producing ultrahigh resolution (for example, 800˜4000 Pixel Per Inch, PPI) Organic Light Emitting Diode (OLED) displays, with the following characteristics: S1, on top of the driving backplane, deposit the first electrode with designed spacing between one another. After that the Pixel Defining Layer (PDL) is deposited and patterned based on the designs of subpixels of the display; S2, on top of the defined subpixel regions from S1, deposit OLED devices, then fabricate the second electrode with the protection layer; S3, on top of the described second electrode with protection layer, deposit the third electrode. The present invention discloses the patterning method to produce OLED devices without using the conventional Metal Masks. Instead, an ultra-thin organic mask is fabricated using the special photolithographic process, and the OLED device structure that include the protection layer to prevent damages to the OLED device from the chemicals used during the processes.

### TECHNICAL FIELD

A manufacture method of organic light emitting diode device production and the optoelectronic displays based on this method are disclosed.

### BACKGROUND ART

AMOLED (Active Matrix Organic Light Emitting Diode Display) is a solid state display device that is composed of organic light emitting diodes based on the stacking of organic semiconductor and other thin films, according to its subpixel and pixel designs. Comparing to the traditional Liquid Crystal Display (LCD), AMOLED possess the advantageous features of light weight, thin form factor, wide viewing angle, good image quality, fast response time, and wider low temperature operating temperature etc., and thus considered the display of the future. By integrating OLED with different Thin Film Transistor (TFT) array driving backplanes, various high end AMOLED display products may be produced in the market, for the applications such as smart phone, television and smart glasses.

For the micro displays used in the smart glasses products, OLED is directly integrated on the Si-based CMOS driving backplane, by using semiconductor production processes to fabricate ultrahigh resolution semiconductor display. This is the advantage of the miniaturization of the OLED technology. In order to realize this advantage in using OLED for micro display applications, it is required to increase its resolution to higher than 2000 PPI (Pixel Per Inch).

Regarding the production technology of OLED, including both Active-Matrix OLED (AMOLED) and Passive Matrix OLED (PMOLED), due to the high susceptibility of the organic semiconductor material to the damage resulting from reactions with ambient moisture and oxygen, the patterning of OLED devices cannot be achieved by traditional photolithography process which is widely used in semiconductor device production in the industry. Instead, it is achieved by using the thermal evaporation process to deposit small molecular organic semiconductor vapor through the openings of shadow mask, by covering the undesired patterning regions on the substrate with a high precision Fine Metal Mask (FMM), to form the thin film at the uncovered regions. In the thermal evaporation process, the use of precision micro-openings in the Fine Metal Mask to define the regions of organic light emitting device, i.e., the subpixel regions, to produce pixels of the display. Current FMM used is fabricated using the low expansion metal foils having the thickness of 20˜40 μm. In the FMM arrays of the precision micro-openings are fabricated based on the designs of subpixels of the display. The size of the openings is determined by the resolution and the design of the display, which is normally composed of the red, green and blue subpixels. The display used for smart phone has a resolution of 300˜600 PPI, with the size of subpixel in the range of a few tens of microns (m). The precision and quality of the FMM have critical effect to the OLED device produced. Due to the limit of physical dimensions of FMM, the display produced by conventional FMM is limited to a resolution less than 800 PPI. Moreover, the aperture ratio, i.e., the ratio of the emissive area to the display area, decreases drastically for OLED display produced with high resolution FMM. Therefore, to achieve the same brightness, higher current is required to drive the OLED device, and thus its lifetime degrades and reliability suffers for display with increasing resolution. This is the main problem of OLED display, especially for high resolution ones.

From the FMM perspective, the higher the display resolution, the number of pixel density increases per unit area, and thus the smaller the subpixel size needed. This is enabled by the reduction of the precision micro-opening area in the Fine Metal Mask (FMM). The reduction of micro-opening makes the fabrication process more challenging and high production cost. When use the high resolution FMM for OLED production, the frequency of cleaning of FMM after certain number of depositions runs of thermal evaporation will increase to ensure the consistency of deposition, and thus the device performance. More frequent cleaning tends to cause higher damage rate that shortens the lifetime with increased replacement of FMM. All of these will increase the cost of FMM. The large area FMM that is used in current production line of AMOLED fab is composed of multiple strips of FMM that is precisely aligned with tension machine with even stretching forces from both ends and laser welded to attach to the mask frame. During the tension and welding process, the position accuracy and flatness of the FMM need to be maintained properly. Any distortion of the FMM that cause deformation of the opening or variation in flatness will lead to contact variations when FMM is attached to substrate for shadow mask deposition. This could cause the significant variation in OLED patterning and thus the performance variations across the OLED display.

Because of the thickness of the metal foil used for FMM fabrication is in the range of 20˜40 microns, current FMM production process, namely photolithography followed with wet etching of the patterned thin metal foil from both sides, is not possible to produce precision FMM for high resolution displays, for example, 800 PPI or higher. Therefore, the FMM shadow mask used in thermal evaporation process can only be used to produce AMOLED display, with Red-Green-Blue side-by-side (RGB side-by-side) subpixel arrangement designs for resolution lower than 800 PPI, mainly used for smart phone applications.

For OLED display with resolution higher than 800 PPI, different OLED display architecture is required. Currently, high resolution AMOLED is achieved by using the White OLED (WOLED) plus Color Filter (CF) architecture. In this architecture, WOLED is deposited in the thermal evaporation chamber using Clear Metal Mask (CMM), which is also known as Open Mask, with micro-openings. Instead, the large area of WOLED is deposited on backplane substrate, and the definition of Red, Green and Blue subpixels are defined by the additional Color Filter (CF) resins, placed on top of the WOLED, after being precisely aligned, similar to that of Liquid Crystal Display (LCD). Because of the CF maybe fabricated on separate glass substrate by using the conventional photolithography processes, this is the current process to produce high resolution AMOLED displays for micro-display applications, such as view finder of video camera or smart glasses, namely Virtual Reality (VR), Augmented Reality (AR), and Mixed Reality (MR) applications.

### DISCLOSURE

### Technical Problem

An embodiment provides Organic Light Emitting Diode (OLED) device patterning process that produces Organic Light Emitting Diode device

Another embodiment provides Organic Light Emitting Diode (OLED) device with high efficiency and good performance in reliability and lifetime.

Another embodiment provides the AMOLED display containing the Organic Light Emitting Diode devices with good performance in image quality, reliability and lifetime.

### Technical Solution

According to an embodiment, Organic Light Emitting Device is produced with a new patterning process, without the use of Fine Metal Mask (FMM). Instead, the patterning process to produce OLED is achieved by the use of special photolithography process together with OLED device structure. The method described may produce ultra-high-resolution OLED displays, including both AMOLED or PMOLED, possessing good display performance.

The patterning process to produce OLED display includes the following:

S1, on top of the driving backplane, deposit the first electrode with designed spacing between one another, based on the requirement of the display. After that the Pixel Defining Layer (PDL) is deposited and patterned according to the spacing between different subpixels;

S2, on top of the subpixel regions deposit OLED devices, then fabricate the second electrode with the protection layer;

S3, on top of the described second electrode with protection layer, deposit the third electrode.

As an example, the described process S2 that produces OLED display device includes the following steps:

S201, on top of the first electrode and PDL deposit the common layers, including Hole Injection Layer (HIL) and Hole Transport Layer (HTL), on all of the subpixel areas;

S202, Apply the first photoresist layer and the second photoresist layer;

S203, Expose the top photoresist on the subpixel areas for the deposition of the first color of the OLED with a photolithography system;

S204, Develop the exposed top photoresist to remove exposed photoresist, followed by dissolving the bottom photoresist polymer layer with the selected solvent, to form a thin organic mask for the patterning of subsequent OLED device deposition;

S205, Deposit the remaining of the layers of the OLED device of the first color sequentially at the areas that photoresists are removed by S204 to form the complete OLED device at those subpixel regions. The described OLED may be one of the Red subpixel OLED devices, Green subpixel OLED device, or Blue subpixel OLED device. The described remaining layers of the OLED device includes red light emitting layer or green light emitting layer, or blue light emitting layer, Electron Transport Layer (ETL), Electron Injection Layer (EIL) and the protective second electrode;

S206, Strip off the first and the second photoresist layers and the undesired remaining layers of the first color OLED on top of them, at the non-subpixel regions;

S207, Repeat the steps S202˜S206, to complete the production of the Red subpixel OLED devices, Green subpixel OLED devices, and Blue subpixel OLED devices that are required by the OLED display.

As an example, the described S2 process to produce OLED device includes:

S201, Apply the first photoresist and the second photoresist layers to form a bi-layer structure on the described first electrode and the Pixel Define layer (PDL)

202, Expose the top photoresist on the subpixel areas for the first color of the OLED with a photolithography system;

S204, Develop the exposed top photoresist to remove photoresist at the exposed regions, followed by dissolving the underneath first photoresist polymer layer with the selected solvent;

S205, Deposit the layers of the whole OLED device of the first color sequentially at the areas that photoresists are removed to form the complete OLED device at those subpixel regions. The described OLED may be one of the Red subpixel OLED devices, Green subpixel OLED device, or Blue subpixel device. The described layers of the whole OLED device include the Hole Injection Layer (HIL), Hole Transport Layer (HTL), red light emitting layer or green light emitting layer or blue light emitting layer, Electron Transport Layer (ETL), Electron Injection Layer (EIL) and the protective second electrode;

S206, Strip off the first and the second photoresist layers and the undesired layers of the first color OLED on top of them, at the non-subpixel regions;

S207, Repeat the steps S201˜S206, to complete the production of the Red subpixel OLED devices, Green subpixel OLED devices, and Blue subpixel OLED devices that are required of the OLED display.

As an example, the described process S2 that produces OLED display device includes the following steps:

S201, S201, Apply the first photoresist and the second photoresist layers on the described first electrode and the Pixel Define layer (PDL)

S202, Expose the top photoresist on all of the subpixel regions for the OLED devices with a photolithography system;

S204, Develop the exposed top photoresist to remove the photoresist at the exposed regions, followed by dissolving the underneath photoresist polymer layer with the selected solvent;

S205, Deposit the layers of the whole White OLED device at all of the areas that photoresists are removed to form the complete White OLED device at those subpixel regions. The described White OLED device may possess a Tandem structure, consisting of Red, Green and Blue subunits stacking vertically, or other subunit combinations, such as Yellow and Blue subunits stacking vertically. Afterwards, the second electrode with protection layer is deposited on the white OLED device;

S206, Strip off the first and the second photoresist layers and the undesired layers of the White OLED device on top of them, at the non-subpixel regions;

As an example, the after the described process S3 includes:

S4 Fabricate the first barrier layer on the third electrode;

S5, On the first barrier layer, fabricate the Color Filter (CF) layers corresponding to the selected subpixel regions for the desired color;

S6, Fabricate the second barrier layer on the Color Filter (CF) layers;

As an example, the described Color Filter (CF) layer includes Red CF, Green CF, Blue CF and Transparent CF layer.

As an example, the White OLED device possesses vertical stacking structure that contains at least one light emitting subunit, one organic light emitting subunit stacking vertically to form a tandem structure; each light emitting subunit contains at least one organic semiconductor layer. For example, the Hole Injection Layer (HIL), Hole Transport Layer (HTL), Emitting Layer (EML), Electron Transport Layer (ETL), Electron Injection Layer (EIL). The protective second electrode is deposited on the Electron Injection layer (EIL) of the uppermost subunit;

As an example, the described White OLED device includes the Hole Injection Layer (HIL), Hole Transport Layer (HTL), the first Emitting Layer (EML1), Electron Transport Layer (ETL), Carrier Generating Layer (CGL), Hole Transport Layer (HTL), the second Emitting Layer (EML2), Electron transport layer (ETL), Electron Injection Layer (EIL) and the protective second electrode.

### Advantageous Effect

The ultra-high resolution Organic Light Emitting Diode (OLED) display with good reliability and performance may be realized by using the OLED devices produced by the disclosed production method.

### DESCRIPTION OF THE DRAWINGS

The advantages of this invention are become obvious from the description below, or can be understood through the practices of this invention with the following illustrative examples.

FIG. 1 The process diagram to produce high resolution Red-Green-Blue Side-by-Side AMOLED display based on Example 1;

FIG. 1-2 The illustration diagram for the step S1002 described in Example 1;

FIG. 1-3 The illustration diagram for the step S1003 described in Example 1;

FIG. 1-4 The illustration diagram for the step S1004 described in Example 1;

FIG. 1-5 The illustration diagram for the step S1005 described in Example 1;

FIG. 1-6 The illustration diagram for the step S1006 and S1007 to deposit the Red subpixel OLED devices, described in Example 1;

FIG. 1-7 The illustration diagram for the step S1008 described in Example 1;

FIG. 1-8 The illustration diagram for the repetitive steps S1003˜S1008 to deposit the Green subpixel OLED devices, described in Example 1;

FIG. 1-9 The illustration diagram for the repetitive steps S1003˜S1008 to deposit the Blue subpixel OLED devices, described in Example 1;

FIG. 1-10 The illustration diagram for the step S1009 described in Example 1;

FIG. 2 The process diagram to produce high resolution Red-Green-Blue Side-by-Side AMOLED display based on Example 2;

FIG. 2-1 The illustration diagram for the step S2001 described in Example 2;

FIG. 2-2 The illustration diagram for the step S2002 described in Example 2;

FIG. 2-3 The illustration diagram for the step S2003 described in Example 2;

FIG. 2-4 The illustration diagram for the step S2004 described in Example 2;

FIG. 2-5 The illustration diagram for the step S2005 and S2006 to deposit the Red subpixel OLED devices, described in Example 2;

FIG. 2-6 The illustration diagram for the step S2007 described in Example 2;

FIG. 2-7 The illustration diagram for the repetitive steps S2002˜S2007 to deposit the Green subpixel OLED devices, described in Example 2;

FIG. 2-8 The illustration diagram for the repetitive steps S2002˜S2007 to deposit the Blue subpixel OLED devices, described in Example 2;

FIG. 2-9 The illustration diagram for the step S2008 described in Example 2;

FIG. 3 The process diagram to produce high resolution AMOLED display, with White OLED plus Color Filters architecture, based on Example 3;

FIG. 3-1 The illustration diagram for the step S3001 described in Example 3;

FIG. 3-2 The illustration diagram for the step S3002 described in Example 3;

FIG. 3-3 The illustration diagram for the step S3003 described in Example 3;

FIG. 3-4 The illustration diagram for the step S3004 described in Example 3;

FIG. 3-5 The illustration diagram for the steps S3005 and S3006 described in Example 3;

FIG. 3-6 The illustration diagram for the step S3007 described in Example 3;

FIG. 3-7 The illustration diagram for the step S3008 described in Example 3;

FIG. 3-8 The illustration diagram for the fabrication of the first barrier layer described in Example 3;

FIG. 3-9 The illustration diagram for the fabrication of the Color Filter layers described in Example 3;

FIG. 3-10 The illustration diagram for the fabrication of the second barrier layer described in Example 3;

FIG. 4 The illustration diagram for the step S3005, structure of the White OLED device, described in Example 3;

FIG. 5 The illustration diagram for the step S3005, another structure of the White OLED device, described in Example 3;

### DESCRIPTION OF SYMBOLS

100, driving backplane;
110, the first electrode;
120, Pixel Defining Layer (PDL);
130, Hole Injection Layer (HIL) and Hole Transport Layer (HTL);
140, the first photoresist;
150, the second photoresist;
160b, the protective second electrode;
160R, the Red subpixel OLED device described in Example 1;
160G the Green subpixel OLED device described in Example 1;
160B, the Blue subpixel OLED device described in Example 1;
170, the third electrode;
190R, the Red subpixel OLED device described in Example 2;
190G, the Green subpixel OLED device described in Example 2;
190B, the Blue subpixel OLED device described in Example 2;
160W, the White OLED device described in Example 3;
180, the first barrier layer;
210R, the red Color Filter described in Example 3;
210G, the green Color Filter described in Example 3;
210B, the blue Color Filter described in Example 3;
210W, the transparent Color Filter described in Example 3;
200, the second barrier layer;
a indicates the process step to coat the first photoresist and the second photoresist;
b indicates the exposure step by using a photolithography tool;
c indicates the development and the dissolution steps of the exposed photoresists;
d indicates the processes of depositing the OLED device layers and the second electrode with protection layer;
e indicates the processes to strip off the first and the second photoresists;
f indicates the process to deposit the third electrode;
g indicates the deposition of the first barrier layer;
h represents the fabrication process of the color filters;
i represents the deposition process of the second barrier layer.

### BEST MODE

Hereinafter embodiments of the present invention are described with detailed examples. These embodiments are exemplary; the present invention in not limited thereto, and the present invention is defined by the scope of claims.

Hereinafter the embodiments of the present invention are described with illustrative figures to describe in details the fabrication method of Organic Light Emitting Diode (OLED) devices and the OLED display produced thereof.

The present invention discloses the production method of Organic Light Emitting Diode (OLED) devices, including:

S1, Deposit the first electrode with designed spacing between one another, based on the requirement of the display. After that the Pixel Defining Layer (PDL) is deposited and patterned according to the spacing between different subpixels. The active matrix driving backplane may be produced on glass, flexible substrates or silicon wafer, with Low Temperature Poly-silicon Thin Film Transistors (LTPS TFT), or Oxide Semiconductor Thin Film Transistors (Oxide TFT), or Complimentary Metal-Oxide-Semiconductor (Si-based CMOS) field-effect transistors fabricated directly on silicon wafer. The first electrode may be transparent conductor layer, such as conductive transparent metal oxides, for example, Indium-Tin-Oxide (InSnₓO_{y}), Indium-Zinc Oxide (InZnₓO_{y}), Aluminum-Tin-Oxide (AlSnₓO_{y}), Indium-Germanium Oxide (IGO) etc.;

S2, on top of the subpixel regions deposit OLED devices, then fabricate the second electrode with the protection layer; The second electrode with protection layer maybe formed by the stacking structure of thin transparent organic, inorganic conductive or dielectric layers; For example,

PEDOT:PSS (Poly3,4-ethylenedioxythiophene-poly(styrene-sulfonate), PETE (polyethyleneimine-ethoxylated), BCP(bathocuproine), graphene, Carbon nanotube(CNTs), Silver (Ag) nanowires, Magnesium (Mg), gold (Au), Silver(Ag), Barium(Ba), Calcium(Ca), Erbium(Er), Ytterbium (Yb), Magnesium alloy (MgAg, Mgln), Aluminum Alloy (AlLi, AlMg, AlCa), Indium-Tin-Oxide (ITO/InSnₓO_{y}), Indium-Zinc Oxide (IZO/InZnₓO_{y}), Aluminum-Tin-Oxide (ATO/AlSnₓO_{y}), Indium-Germanium Oxide (IGO), Aluminum-doped SiO (Al—SiO), Lithium Fluoride (LiF), Lithia (Li₂O), Molybdenum oxide (MoO₃), Vanadium pentoxide(V₂O₅), oxide/metal/oxide (OMO, such as ITO/Ag/ITO) stacking structure etc.

S3, on top of the described second electrode with protection layer, deposit the third electrode. The third electrode may be transparent conductor layer, such as conductive transparent metal oxides, for example, Indium-Tin-Oxide (InSnₓO_{y}), Indium-Zinc Oxide (InZnₓO_{y}), Aluminum-Tin-Oxide (AlSnₓO_{y}), Indium-Germanium Oxide (IGO) etc.

The present invention discloses the patterning method to produce ultra-high resolution Organic Light Emitting Diode (OLED) display without using the high precision Fine Metal Mask (FMM), instead the OLED devices are patterned by using a special photolithography process together with the required device structures. The OLED display produced by this process possesses superior display performance and reliability properties.

Depending on the difference of the production processes described in S2 for OLED device fabrication, three types (but not limited to) of AMOLED displays can be produced, including:

1. High resolution Red-Green-Blue Side-By-Side (RGB SBS) AMOLED display;
2. Another high-resolution Red-Green-Blue Side-By-Side (RGB SBS) AMOLED display;
3. High resolution White OLED plus Color Filters (WOLED+CF) AMOLED display.
The production process for these three types of AMOLED display is described below.

Moreover, although the examples described herein are production of the Active-Matrix organic Light Emitting Diode (AMOLED) displays, the process disclosed in present invention is applicable to produce Passive Matrix Organic Light Emitting Diode (PMOLED) displays by replacing the active matrix driving backplane with the passive matrix driving backplanes.

### EXAMPLE 1

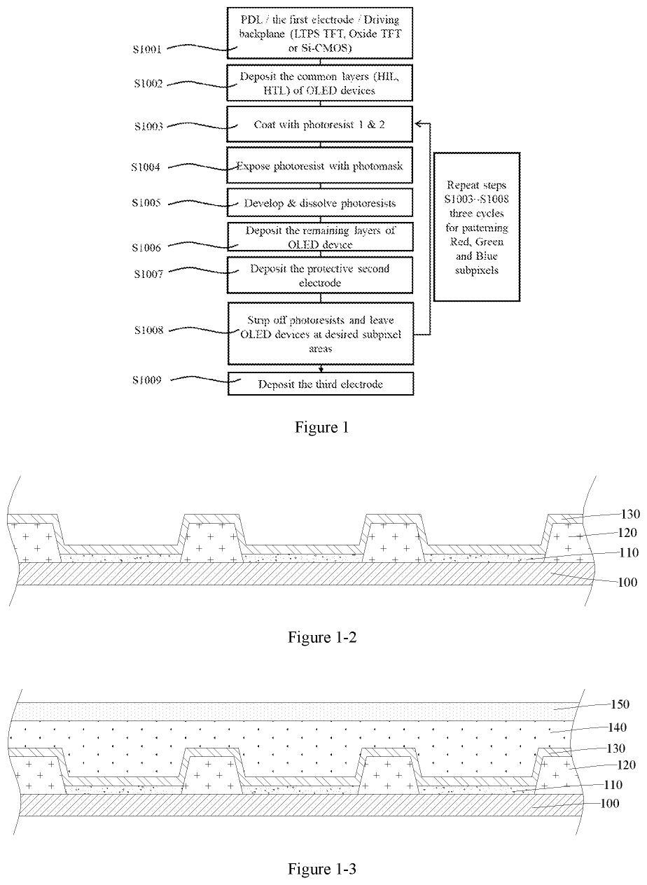

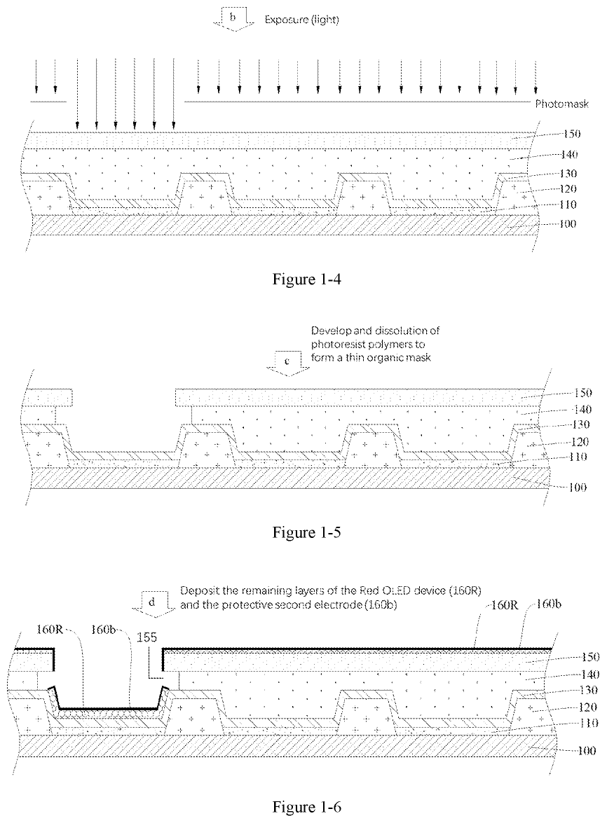

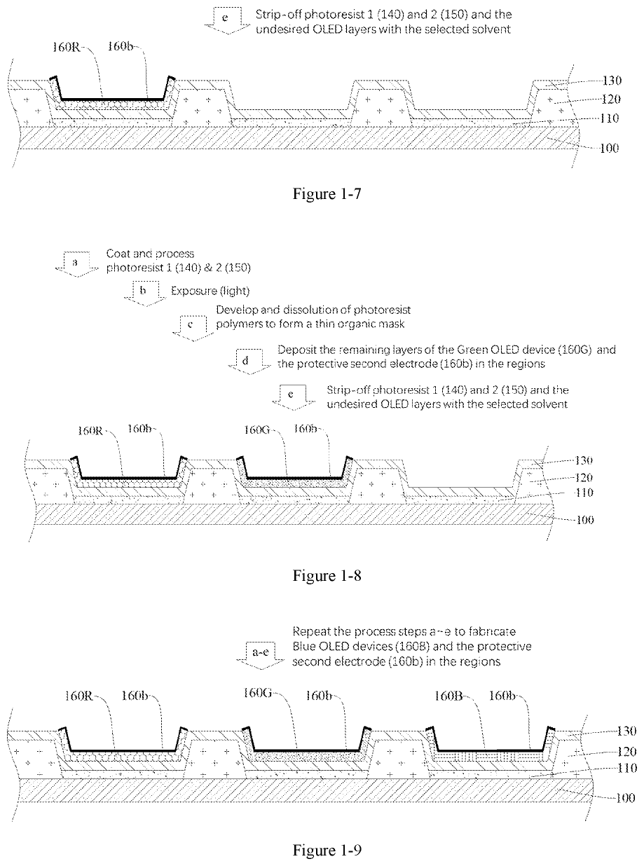

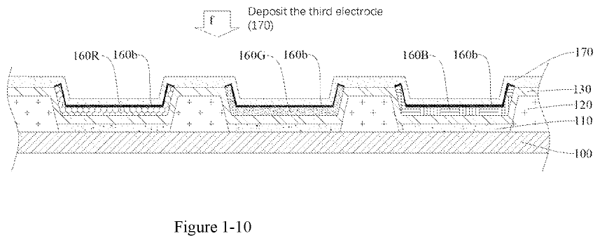

As shown in FIG. 1, the present example describes the production method to fabricate a RGB SBS display, includes:

S1001, Deposit the first electrode with designed spacing between one another, based on the requirement of the display. After that the Pixel Defining Layer (PDL) is deposited and patterned according to the spacing between different subpixels, to define subpixel regions for OLED device fabrication;

S1002, on top of the first electrode and PDL deposit the common layers, including Hole Injection Layer (HIL) and Hole Transport Layer (HTL), on all of the subpixel areas;

S1003, Apply the first photoresist layer and the second photoresist layer. The photoresist materials may be ordinary photoresist resins, which are photosensitive polymer materials. They can be the negative type photoresist which will polymerized (by photo-polymerization or photo cross-linking reactions) when exposed to the required wavelengths of light. For example (but not limited to), methyl methacrylate series, or fluoroalkyl series of photosensitive polymer materials, crosslink reactions occur when exposed to the required light; the photoresist may also be the positive type that photo-decomposition reactions take place when irradiate with the required light, for example, diazo naphthoquinone, DNQ series materials etc. The photoresist materials are not limited to the examples provided. As the major selection criteria, the solvent used to dissolve the photoresist materials is selected not to damage the film materials used in the OLED device.

S1004, Photo expose the upper photoresist at the desired subpixel regions, to pattern for the deposition of the first color OLED devices, using the photo mask and the photolithography system.

S1005, Develop the exposed photoresist, followed by patterning the photoresist polymer layer underneath by dissolving it with the selected solvent

S1006, Deposit the remaining material for the layers of the OLED device of the first color sequentially at the areas that photoresists are removed to form the complete OLED device at those subpixel regions. The described OLED may be one of the Red subpixel OLED devices, Green subpixel OLED device, or Blue subpixel OLED device. The described remaining layers of the OLED device includes red light emitting layer or green light emitting layer, or blue light emitting layer, Electron Transport Layer (ETL), Electron Injection Layer (EIL);

S1007, On the Electron Injection Layer (EIL) of completed OLED device, deposit the material for the protective second electrode; when depositing the material for the OLED device and the material for the protective second electrode on top of the photoresist layer, a plurality of discontinuous gaps are formed and the gap exposes the photoresist layer. These discontinuous gaps are formed around the bilayer photoresist structures resulting from the discontinuous coverage of the deposited films on top of these structures due to their overhang structure and height, compared to that of the thickness of the materials deposited.

S1008, Strip off the first and the second photoresist layers and the undesired remaining layers of the first color OLED on top of them, at the non-subpixel regions by exposing unprotected photoresist layers through the previously formed gaps. The selection criteria for the solvent used to dissolve the photoresists is that the solvent will not cause chemical reaction and damage the OLED devices deposited during this stripping process.

Repeat the steps S1003˜S1008, to complete the production of the Red subpixel OLED devices, Green subpixel OLED devices, and Blue subpixel OLED devices that are required of the OLED display.

S1009, Fabricate the third electrode on the second electrode and protection layer previously deposited;

More detailed description of the production processes is provided below, based on the processing steps illustrated from FIG. 1-2 to FIG. 1-10:

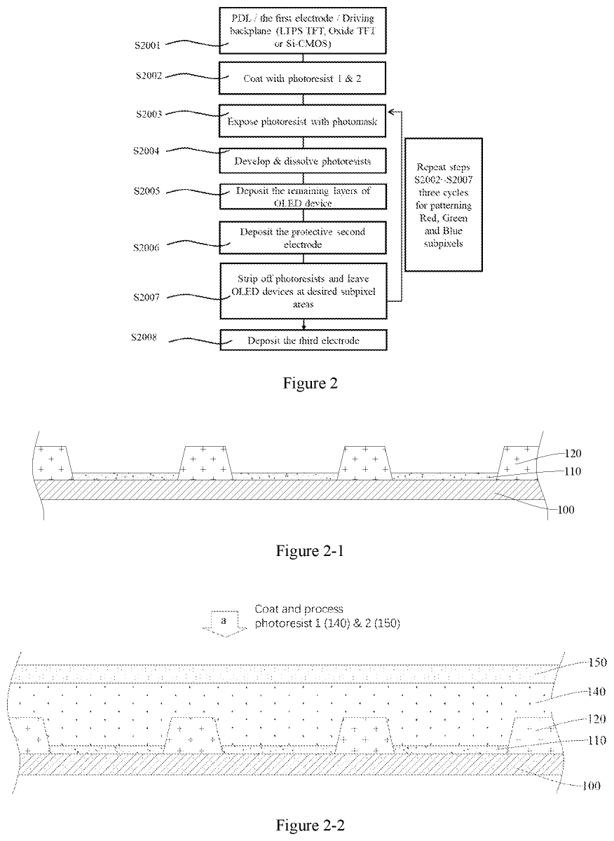

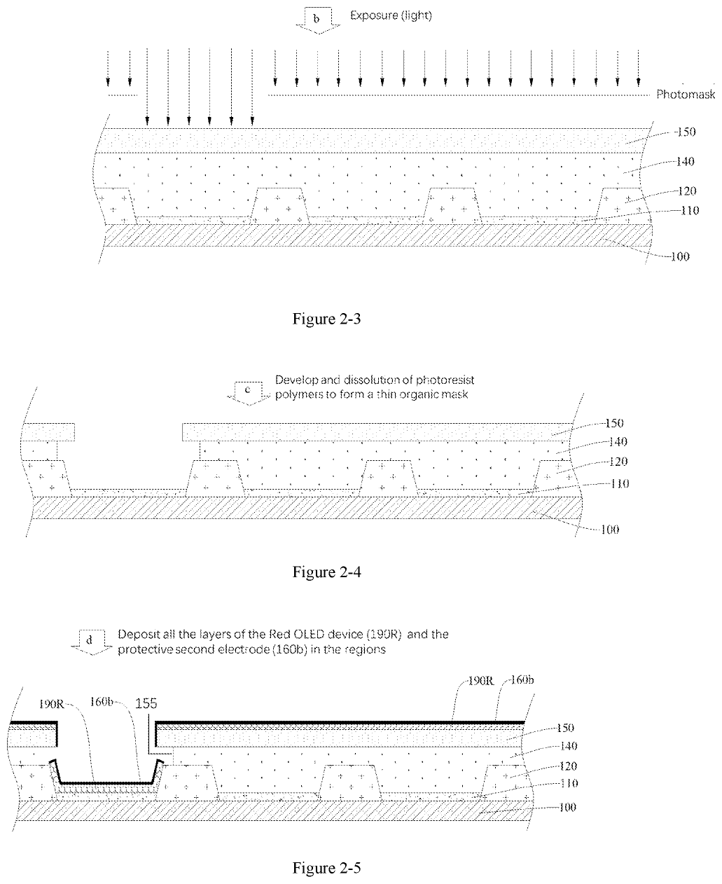

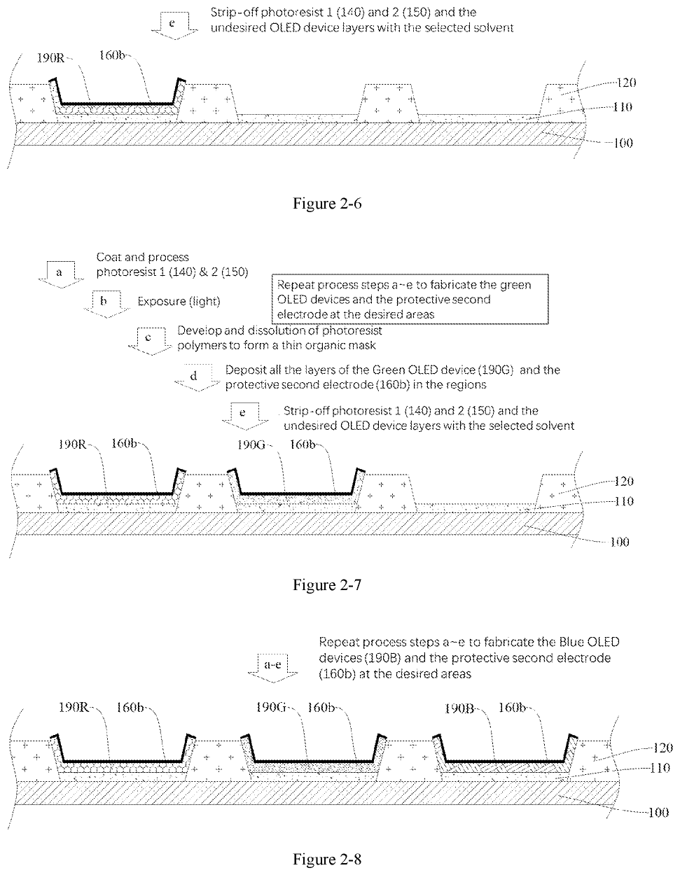

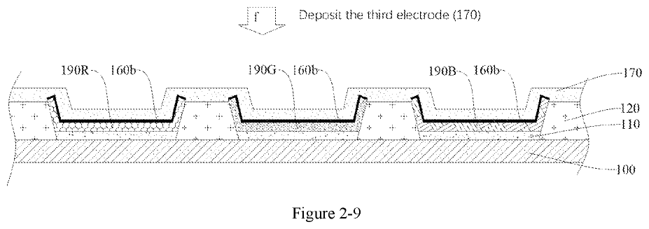

As shown in FIG. 1-2, with the above-mentioned processing steps S1001 and S1002, the first electrode 110 and the Pixel Defining Layer (PDL) 120 are deposited on the active matrix driving backplane substrate; forming the subpixel regions with designed spacing between one another, based on the design requirements of the AMOLED display. On the first electrode 110 and PDL 120, deposit the common layers, such as Hole Injection Layer (HIL) and Hole Transport Layer (HTL) 130, of the OLED devices on all of the patterned subpixel regions;

As shown in FIG. 1-3, following the processing step S1003 described above, the process steps a is to sequentially coat and process the first photoresist 140 and the second photoresist layer 150 on the HIL and HTL 130;

As shown in FIG. 1-4, following the processing step S1004 described above, the step b is to expose the photoresist 150 and 140 with a photo mask in the photolithography tool to pattern them according to the design of the subpixels of the display;

As shown in FIG. 1-5, following the processing step S1005 described above, the step c is taken to develop and dissolve the exposed photoresists 150 and 140 sequentially;

As shown in FIG. 1-6, following the processing step S1006 described above, the step d is taken to deposit the remaining thin film layers of the OLED devices for the subpixel regions patterned by the photoresists 150 and 140. FIG. 1-6 also shows gap 155 around overhang structure of the bilayer photoresist mask regions, resulted from discontinuous coverage of the deposited film on the top. For example, if the Red OLED device 160R is selected for these patterned subpixels, then its red emitting layer, electron transport layer, the electron injection layer and the second electrode with protection layer are deposited sequentially to form the complete Red OLED devices 160R as the red subpixels for the OLED display;

As shown in FIG. 1-7, following the processing step S1008 described above, take the step e to strip off the first photoresist 140 and the second photoresist 150 and the undesired OLED layers on top of them from the non-subpixel regions by exposing the whole workpiece in the selected solvent. The main selection criteria of the solvent used is that it will effectively dissolve the first photoresist 140 and cause the removal of the second photoresist 150 on top, but it will not react and damage the OLED devices deposited during the stripping process e;

As shown in FIG. 1-8, repeating the processing steps a˜e described above, pattern the subpixel regions with the photoresist and the photolithography processes for the other color of OLED devices at their subpixel regions designed for the AMOLED display. For example, to fabricate the Green OLED device 160G, deposit the green emitting layer, electron transport layer, electron injection layer and the second electrode and the protection layer at the newly patterned subpixel regions to form the complete Green OLED devices 160G as green subpixels for the OLED display. Striping off the first photoresist 140 and the second photoresist 150 and the undesired OLED layers on top of them from the non-subpixel regions by exposing the whole workpiece in the selected solvent. The main selection criteria of the solvent used is that it will effectively dissolve the first photoresist 140 and cause the removal of the second photoresist 150 on top, but it will not react and damage the OLED devices deposited during the stripping process;

As shown in FIG. 1-9, repeating the processing steps a˜e described above, pattern the subpixel regions with the photoresist and the photolithography processes for the remaining color of OLED devices at their subpixel regions designed for the AMOLED display. In this case, the Blue OLED device 160B are fabricated by depositing the blue emitting layer, electron transport layer, electron injection layer and the second electrode and the protection layer at the newly patterned subpixel regions to form the complete Blue OLED devices 160B as blue subpixels for the OLED display. Stripping off the first photoresist 140 and the second photoresist 150 and the undesired OLED layers on top of them from the non-subpixel regions by exposing the whole workpiece in the selected solvent. The main selection criteria of the solvent used is that it will effectively dissolve the first photoresist 140 and cause the removal of the second photoresist 150 on top, but it will not react and damage the OLED devices deposited during the stripping process;

As shown in FIG. 1-10, after fabricating the Red OLED devices 160R, Green OLED devices 160G, Blue OLED devices 160B and the second electrode with protective layer 160b, the step f is taken to fabricate the third electrode 170, as described by processing step S1009. With the processing steps described above, based on the illustrations of FIG. 1-1 FIG. 1-10, and further encapsulation to passivate the AMOLED display device an AMOLED display panel with RGB side-by-side architecture can be made. After AMOLED panel process, the module processes are followed to attach the driving electronics and circuit boards, touch panel function for user interface, polarizer film to reduce ambient reflection and the protective cover on top the display, an AMOLED display product may be completed for the market place.

### EXAMPLE 2

As shown in FIG. 2, another production method to fabricate an RGB Side-by-Side AMOLED display is described, includes:

S2001, Deposit the first electrode with designed spacing between one another, based on the requirement of the display. After that the Pixel Defining Layer (PDL) is deposited and patterned according to the spacing between different subpixels, to define subpixel regions for OLED device fabrication;

S2002, Apply the first photoresist layer and the second photoresist layer on the patterned PDL and the first electrode;

S2003, Photo expose the photoresists at the desired subpixel regions, to pattern for the deposition of the first color OLED devices, using the photo mask and the photolithography system.

S2004, Develop the exposed photoresist, followed by patterning the photoresist polymer layer underneath by dissolving it with the selected solvent;

S2005, Deposit the complete layers of the OLED device of the first color sequentially at the areas that photoresists are removed to form the complete OLED device at those subpixel regions. The described OLED may be one of the Red or Green or Blue subpixel OLED devices. The described complete layers of the OLED device may include Hole Injection Layer (HIL), Hole Transport Layer (HTL), red light emitting layer or green light emitting layer, or blue light emitting layer, Electron Transport Layer (ETL), Electron Injection Layer (EIL);

S2006, On the Electron Injection Layer (EIL) of completed OLED device, deposit the protective second electrode;

S2007, Strip off the first and the second photoresist layers and the undesired remaining layers of the first color OLED on top of them, at the non-subpixel regions. The selection criteria for the solvent used to dissolve the photoresists is that the solvent may dissolve the photoresist effectively, but will not cause chemical reaction and damage the OLED devices deposited during this stripping process.

Repeat the steps S2002˜S2007, to complete the production of the Red subpixel OLED devices, Green subpixel OLED devices, and Blue subpixel OLED devices that are required of the OLED display.

S2008, Fabricate the third electrode on the second electrode and protection layer previously deposited;

More detailed description of the production processes is provided below, based on the processing steps illustrated from FIG. 2-1 to FIG. 2-9:

As shown in FIG. 2-1, with the above-mentioned processing step S2001, the first electrode 110 and the Pixel Defining Layer (PDL) 120 are deposited on the active matrix driving backplane substrate 100; forming the subpixel regions with designed spacing between one another, based on the design requirements of the AMOLED display.

As shown in FIG. 2-2, following the processing step S2002 described above, the process steps a is taken to sequentially coat and process the first photoresist 140 and the second photoresist layer 150 on the patterned first electrode 110 and the PDL 120;

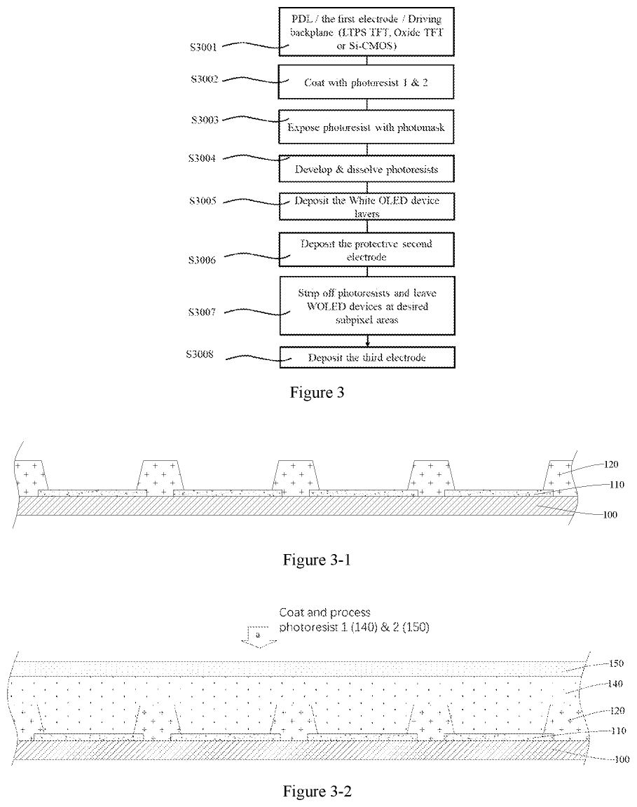

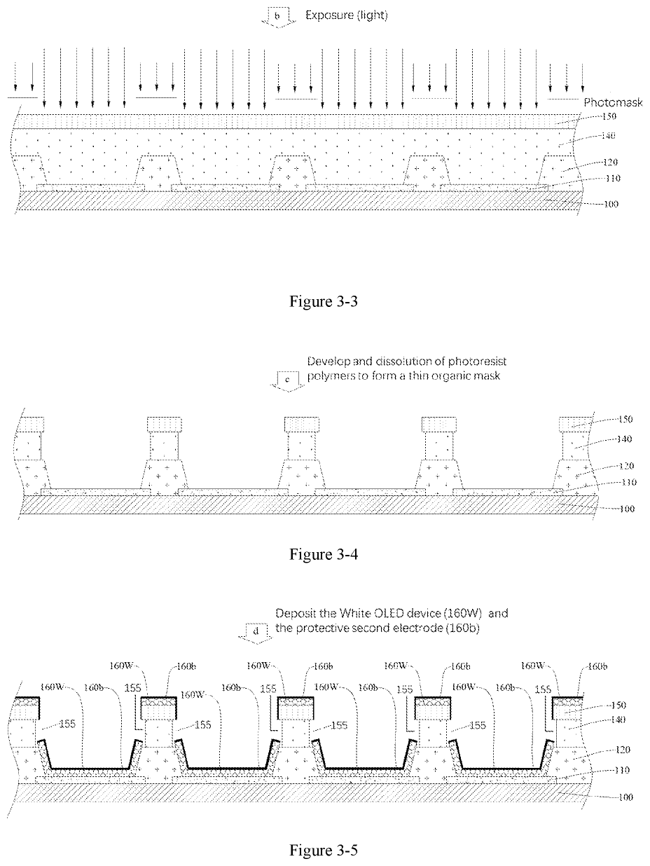

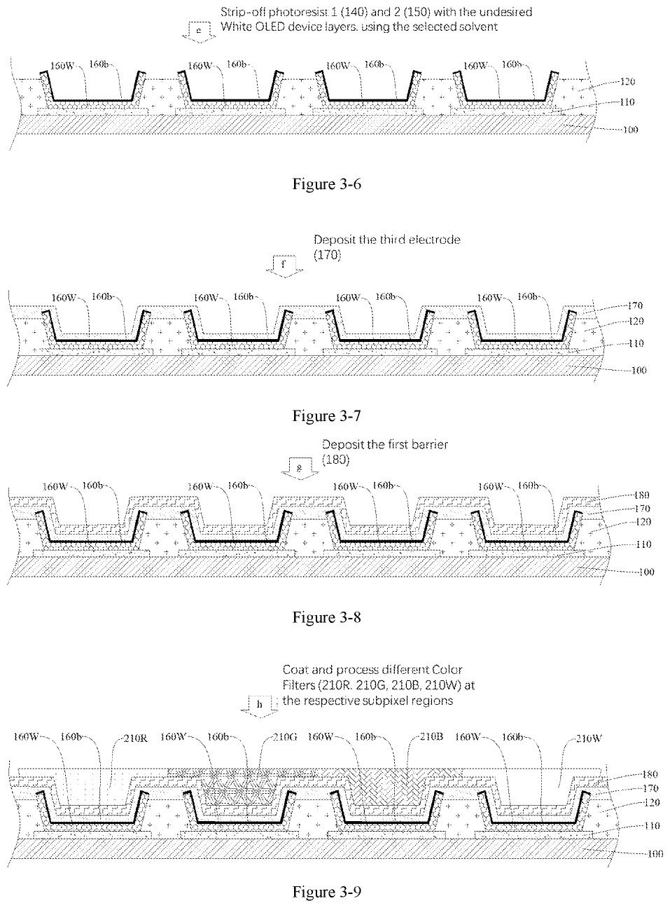

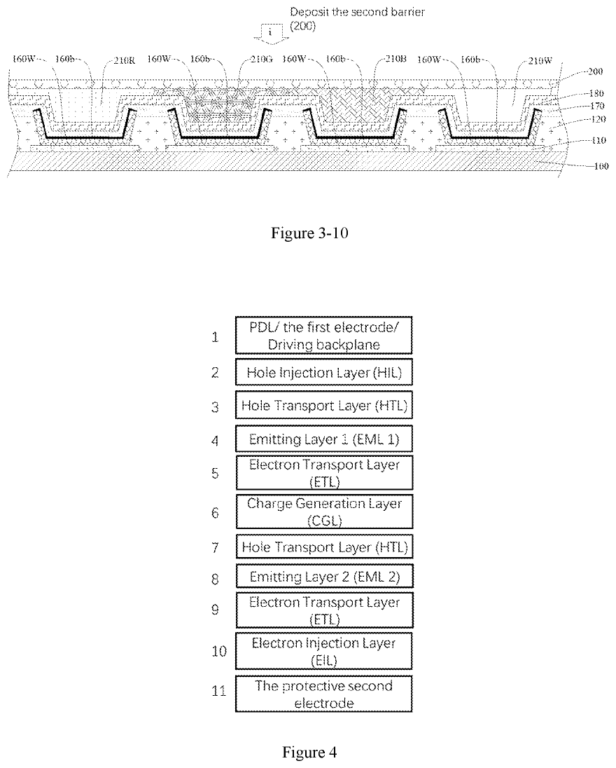

As shown in FIG. 2-3, following the processing step S2003 described above, the step b is to expose the photoresist 150 and 140 with a photo mask in the photolithography tool to pattern them according to the design of the subpixels of the display;

As shown in FIG. 2-4, following the processing step S2004 described above, the step c is taken to develop and dissolve the exposed photoresists 150 and 140 sequentially;

As shown in FIG. 2-5, following the processing step S2005 described above, the step d is taken to deposit the complete thin film layers of the OLED devices for the subpixel regions patterned by the photoresists 150 and 140. For example, in this case, the Red OLED device 190R is selected for these patterned subpixels, then its Hole Injection Layer (HIL), Hole Transport Layer (HTL), red emitting layer, electron transport layer, the electron injection layer and the second electrode with protection layer are deposited sequentially to form the complete Red OLED devices 190R as the red subpixels for the OLED display;

As shown in FIG. 2-6, following the processing step S2006 described above, take the step e to strip off the first photoresist 140 and the second photoresist 150 and the undesired OLED layers on top of them from the non-subpixel regions by exposing the whole workpiece in the selected solvent. The main selection criteria of the solvent used is that it will effectively dissolve the first photoresist 140 and cause the removal of the second photoresist 150 on top, but it will not react and damage the OLED devices deposited during the stripping process e;

As shown in FIG. 1-8, repeating the processing steps a˜e described above, pattern the subpixel regions with the photoresist and the photolithography processes for the other color of OLED devices at their subpixel regions designed for the AMOLED display. For example, to fabricate the Green OLED device 190G, deposit its Hole Injection Layer (HIL), Hole Transport Layer (HTL), green emitting layer, electron transport layer, electron injection layer and the second electrode and the protection layer at the newly patterned subpixel regions to form the complete Green OLED devices 190G as green subpixels for the OLED display. Striping off the first photoresist 140 and the second photoresist 150 and the undesired OLED layers on top of them from the non-subpixel regions by exposing the whole workpiece in the selected solvent. The main selection criteria of the solvent used is that it will effectively dissolve the first photoresist 140 and cause the removal of the second photoresist 150 on top, but it will not react and damage the OLED devices deposited during the stripping process;

As shown in FIG. 2-8, repeating the processing steps a˜e described above, pattern the subpixel regions with the photoresist and the photolithography processes for the remaining color of OLED devices at their subpixel regions designed for the AMOLED display. In this case, the Blue OLED device 190B are fabricated by depositing its Hole Injection Layer (HIL), Hole Transport Layer (HTL), the blue emitting layer, electron transport layer, electron injection layer and the second electrode and the protection layer at the newly patterned subpixel regions to form the complete Blue OLED devices 190B as blue subpixels for the OLED display. Striping off the first photoresist 140 and the second photoresist 150 and the undesired OLED layers on top of them from the non-subpixel regions by exposing the whole workpiece in the selected solvent. The main selection criteria of the solvent used is that it will effectively dissolve the first photoresist 140 and cause the removal of the second photoresist 150 on top, but it will not react and damage the OLED devices deposited during the stripping process;

As shown in FIG. 2-9, after fabricating the Red OLED devices 190R, Green OLED devices 190G, Blue OLED devices 190B and the second electrode with protective layer 160b, the step f is taken to fabricate the third electrode 170, as described by processing step S2008.

With the processing steps described above, based on the illustrations of FIG. 2-1˜FIG. 2-9, and further encapsulation to passivate the AMOLED display device another way of AMOLED display panel with RGB side-by-side architecture can be made. After AMOLED panel process, the module processes are followed to attach the driving electronics and circuit boards, touch panel function for user interface, polarizer film to reduce ambient reflection and the protective cover on top the display, an AMOLED display product may be completed for the market place.

Example 1 and Example 2 illustrate the production method by using the combination of the device fabrication procedures and the design of OLED device structure to protect the deposited OLED devices, to reduce the possible damages resulting from the contact between processing chemicals to the OLED devices during production of the OLED display. Using the normal photoresist and the benign photoresist polymer combination to form the organic masking structure to pattern the OLED device in the thermal evaporation process, as replacement to the traditional high precision Fine Metal Mask (FMM). Due to the use of the thin organic masking structure, the common issues associated to the use of FMM, such as contact contamination or damages to the substrate, shadow effect and the variations and distortions of FMM may be eliminated. Therefore, OLED display with subpixels of larger aperture ratio, dramatic improvement of display and power performance and reliability maybe produced. Moreover, current invention enables the production of ultra-high resolution (for example, 800˜4000 ppi) of AMOLED with RGB Side-by-Side architecture that is unachievable with FMM process. This opens up the new possibilities to produce the ultra-high resolution direct emitting, full color AMOLED displays, including glass-based, flexible substrate-based or Si-based AMOLED displays.

### EXAMPLE 3

As shown by FIG. 3, a production method to produce ultra-high resolution of AMOLED with WOLED plus Color Filter (CF) architecture is described, including:

S3001, Deposit the first electrode with designed spacing between one another, based on the requirement of the display. After that the Pixel Defining Layer (PDL) is deposited and patterned according to the spacing between different subpixels, to define subpixel regions for OLED device fabrication;

S3002, Apply the first photoresist layer and the second photoresist layer on the patterned PDL and the first electrode;

S3003, Photo expose the photoresists at all of the subpixel regions, to pattern for the deposition of the white color OLED devices, using the photo mask and the photolithography system.

S3004, Develop the exposed photoresist, followed by patterning the photoresist polymer layer underneath by dissolving it with the selected solvent; to open up the subpixel regions to complete the patterning for deposition of white OLED device;

S3005, Deposit the white OLED device on all of the patterned subpixel regions;

S3006, deposit the second electrode with protection layer on the deposited white OLED device;

S3007, Strip off the first and the second photoresist layers and the undesired white OLED deposition on top of them, at the non-subpixel regions. The selection criteria for the solvent used to dissolve the photoresists is that the solvent may dissolve the photoresist effectively, but will not cause chemical reaction and damage the OLED devices deposited during the stripping process.

Fabricate the third electrode on the second electrode and protection layer previously deposited;

More detailed description of the production processes is provided below, based on the processing steps illustrated from FIG. 3-1 to FIG. 3-10:

As shown by FIG. 3-1, based on above-mentioned step 3001, deposit the first electrode with designed spacing between one another, based on the requirement of the display. After that the Pixel Defining Layer (PDL) is deposited and patterned according to the spacing between different subpixels, to define subpixel regions for OLED device fabrication;

As shown by FIG. 3-2, based on above-mentioned step 3002, the process steps a is taken to apply the first photoresist layer and the second photoresist layer on the patterned PDL and the first electrode;

As shown by FIG. 3-3, based on above-mentioned step 3003, the process step b is taken to expose the photoresists at all of the subpixel regions, to pattern for the deposition of the white color OLED devices, using the photo mask, with the subpixel designs of the AMOLED display, and the photolithography system.

As shown by FIG. 3-4, based on above-mentioned step 3004, the process step c is taken to develop the exposed photoresist, followed by patterning the photoresist polymer layer underneath by dissolving it with the selected solvent; to open up the subpixel regions to complete the patterning of subpixels for deposition of white OLED device;

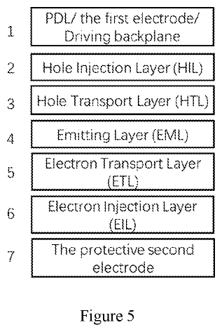

As shown by FIG. 3-5, based on above-mentioned step 3005, the process step d is taken to evaporate white OLED device 160W on all of the subpixel regions. The white OLED device consists one or more light emitting subunits to form a vertical stacking structure. The white OLED device may be formed by stacking one or more light emitting subunits, for example 1 to 4 subunits. The examples of the possible white OLED device structure are shown in FIG. 4 and FIG. 5.

The white OLED device shown in FIG. 4 contains two light emitting layers. It is fabricated by on top of the driving backplane substrate

1 depositing the first electrode followed by Pixel Defining Layer (PDL),
2 then deposit Hole Injection Layer (HIL),

### 3 Hole Transport Layer (HTL),

4 the first Light Emitting Layer,

### 5 Electron Transport Layer (ETL),

### 6 Carrier Generation Layer (CGL),

### 7 Hole Transport Layer (HTL),

8 the second Light Emitting Layer,

### 9 Electron Transport Layer (ETL),

### 10 Electron Injection Layer (EIL),

11 the second electrode with protection layer; The second electrode with protection layer 160b is fabricated on the white OLED device 160W, based on the process step S3006.

The white OLED device in FIG. 5 is a special device that possesses only one emitting layer; the detailed structure contains

1 the first electrode and the PDL on the driving backplane,
2 then Hole Injection Layer (HIL),

### 3 Hole Transport Layer (HTL),

### 4 Light Emitting Layer (EML),

### 5 Electron Transport Layer (ETL),

### 6 Electron Injection Layer (EIL),

7 the second electrode with protection layer; following process step S3006, the second electrode with protection layer 160b is fabricated on the White OLED 160W;

As shown by FIG. 3-6, based on above-mentioned step S3007, the process step e is taken to strip off the first and the second photoresist layers and the undesired white OLED deposition on top of them, at the non-subpixel regions. The selection criteria for the solvent used to dissolve the photoresists is that the solvent may dissolve the photoresist effectively, but will not cause chemical reaction and damage the OLED devices deposited during the stripping process.

As shown by FIG. 3-7, based on above-mentioned step S3008, the process step f is taken to fabricate the third electrode 170 on the previously fabricated second electrode with protection layer 160b;

Furthermore, after the OLED device is completed, on top of that the process step g is taken to fabricate the first barrier layer 180 on top of the third electrode 170;

As shown by FIG. 3-9, on top of the first barrier layer 180, the process step f is taken to coat and process the Color Filters (CF), including the Red Color Filter 210R, Green Color Filter 210G, Blue Color Filter 210B and the transparent Color Filter 210W, at the subpixel regions corresponding to the red, green, blue and brightness enhancement subpixel regions of the desired display. Although this example takes the Red, Green, Blue and Transparent subpixel design, which is also called the RGBW design, present invention is also applicable to other color subpixel combination designs, using different color filter materials to adjust and achieve the desirable color gamut characteristics of the AMOLED display.

As shown by FIG. 3-10, on top of the color filters, the process step i is taken to fabricate the second barrier layer 200;

With the processing steps illustrated above, an ultrahigh resolution full color AMOLED display panel with white OLED plus color filters architecture maybe achieved. The Example 3 illustrates the production method by using combination of the device fabrication procedures and the design of OLED device structure to protect the deposited OLED devices, to reduce the possible damages resulting from the contact between processing chemicals to the OLED devices during production of the OLED display. The AMOLED display produced possesses high performance in display quality, lifetime and reliability. Another important feature of the AMOLED display produced with the disclosed photolithographic patterning processes, using the combination of bilayer photoresist polymers, including conventional photoresist and the special benign optical polymer, lift-off to strip off the undesired photoresists at the non-subpixel regions, with selected solvent after depositing OLED device, resulting in separation between subpixels in the AMOLED display. This physical separation between subpixels prevents the issues of crosstalk due to leakage current caused by the adjacent subpixels that often occur in the high resolution conventional white OLED plus color filter AMOLED display produced by the Clean Metal Mask (CMM) patterning process, in which the blanket white OLED layers are coated in the vacuum deposition system, using the CMM as shadow mask. Therefore, the organic semiconductor layers in the white OLED device are connected between the resulted subpixels of the AMOLED produced.

Using the organic thin mask produced by special bilayer photoresists and photolithographic processes to pattern the subpixel of the AMOLED display of white OLED plus color filter architecture, in replacement of conventional white OLED plus color filter AMOLED produced by CMM patterning process, the separation between subpixels is achieved, which prevent the undesirable current leakage from the adjacent subpixels, and thus effectively reduce the color mixing crosstalk issue and allow the production of high quality, long lifetime, ultrahigh resolution AMOLED display with the white OLED plus color filter architecture.

The patterning process and the OLED device structure disclosed in present invention may be used for production of PMOLED and AMOLED displays for the wearable application, such as ultrahigh resolution microOLED displays used in smart glasses for Virtual Reality (VR), Mixing Reality (MR) and Augmented Reality (AR); electronic skin and displays in automobiles, eBook and ePaper; AMOLED displays used in high end mobile phones, smart phones, notebook computers televisions, and foldable and rollable OLED display products.

In the description in present invention, the terms for describing the relative direction or location, such as “center”, “vertical”, “horizontal”, “upper”, “lower”, “front”, “back”, “left”, “right”, “in”, “out” are used to concisely illustrate the relation of relative location shown in the Figures attached, instead of indicating or implying that the device or setup must possess the specific orientation or directional structure; thus, cannot be viewed as limitation of present invention.

In the description of present invention, “the feature”, “for example” may include one or multiple features or examples, without being listed exhaustively.

In the description of present invention, the terms used “one example”, “some example”, “illustrative example”, “illustration”, “implementation example” or “some illustrations” imply that the characteristics, structure or feature described are included in at least one of the Examples or illustrations. These terms do not necessary indicate the same example or illustration.

Although present invention is illustrated with some Examples, so it is understandable to the normal technical people in the field, there are possible variations, modifications, replacement, and change could be made based on the principles and methods disclosed within. The scope of present invention is defined by the claims and their equivalents.

1. A production method for Organic Light Emitting Diode (OLED) display, with the following characteristics:
S1, on top of the driving backplane, deposit the first electrode with designed spacing between one another, based on the requirement of the display. After that the Pixel Defining Layer (PDL) is deposited and patterned according to the spacing between different subpixels;
S2, on top of the defined subpixel regions from S1, deposit OLED devices, then fabricate the protective second electrode; and
S3, on top of the described protective second electrode, deposit the third electrode.

2-3. (canceled)

4. The OLED device and display produced with claim 1, wherein the process of S2 includes the following steps:
S201, Apply the first photoresist and the second photoresist layers to form a bi-layer structure on the described first electrode and the Pixel Define layer (PDL) on the driving backplane;
S202, Expose the top photoresist on all of the subpixel regions for the OLED devices with a photolithography system;
S204, Develop the exposed top photoresist to remove the photoresist at the exposed regions, followed by dissolving the underneath photoresist polymer layer with the selected solvent;
S205, Deposit the layers of the whole White OLED device at all of the subpixel areas that photoresists are removed to form the complete White OLED device at those subpixel regions. The described White OLED device may possess a Tandem structure, consisting of Red, Green and Blue subunits staking vertically, or other subunit combinations such as Yellow and Blue subunits stacking vertically. Afterwards, the second electrode with protection layer is deposited on the white OLED device; and
S206, Strip off the first and the second photoresist layers and the undesired layers of the White OLED device on top of them, at the non-subpixel regions.

5. The OLED device and display produced with claim 1, wherein after the process of S3 of preparation of the third electrode includes the following steps:
S4, Fabricate the first barrier layer on the third electrode;
S5, On the first barrier layer, fabricate the Color Filter (CF) layers corresponding to the selected subpixel regions for the desired color based on the requirement of the OLED display; and
S6, Fabricate the second barrier layer on the Color Filter (CF) layers.

6. The OLED device and display produced with claim 4, wherein the described Color Filter (CF) layer includes Red CF, Green CF, Blue CF and Transparent CF layer.

7. The OLED device and display produced with claim 5, wherein the white OLED device contain at least one organic light emitting subunit stacking vertically to form a tandem structure; each light emitting subunit contains at least one organic semiconductor layer, such as the Hole Injection Layer (HIL), Hole Transport Layer (HTL), Emitting Layer (EML), Electron Transport Layer (ETL), or Electron Injection Layer (EIL), wherein
the protective second electrode is deposited on the Electron Injection layer (EIL) of the uppermost subunit.

8. The OLED device and display produced with claim 5, wherein the white OLED device contains the Hole Injection Layer (HIL), Hole Transport Layer (HTL), the first Emitting Layer (EML1), Electron Transport Layer (ETL), Carrier Generating Layer (CGL), Hole Transport Layer (HTL), the second Emitting Layer (EML2), Electron transport layer (ETL), Electron Injection Layer (EIL) and the protective second electrode.

9. (canceled)

10. A method for making subpixel device for an Organic Light Emitting Diode (OLED) display on a driving backplane comprising the steps of:
depositing a plurality of first electrodes on top of the driving plane, the plurality of first electrodes being spaced apart;
depositing a pixel defining layer on top of the driving backplane with the plurality of first electrodes, the pixel defining layer defining a plurality of subpixel regions;
depositing a photo resist layer on the driving backplane;
exposing the photoresist layers with a photo mask to transfer pattern from photomask to the photo resist layer covering the driving backplane;;
developing the exposed photo resist layer with selected chemical to form bilayer organic mask structures;
depositing thin layers for the selected color of light emitting device on top of the subpixel regions forming the subpixel device and on top of photo resist layer previously not removed;
depositing a plurality of second electrodes on top of the light emitting layer, the plurality of second electrodes being covered by a protection layer; and
removing the light emitting layers and the second electrodes deposited on top of the photo resist layer previously not removed by dissolving the photo resist layer previously not removed.

11. The method of claim 10 further comprising the step of depositing a common layer on top of the pixel defining layer.

12. The method of claim 11, wherein the step of depositing a photo resist layer on the driving backplane further comprise depositing the photo resist layer on top of the common layer.

13. The method of claim 11, wherein the step of depositing the common layer further comprises depositing a hole injection layer and a hole transport layer.

14. The method of claim 10, wherein the step of depositing the photo resist layer further comprises depositing a first photo resist layer and depositing a second photo resist layer.

15. The method of claim 10 further comprising the step of forming the driving backplane on a flexible substrate.

16. The method of claim 10, wherein dissolving the photo resist layer not previously removed further comprises a solvent entering contact with the photo resist layer through a through gap formed on the light emitting layer and the protective second electrodes.

17. The method of claim 10 further comprising the step of depositing a plurality of third electrodes on top of the second electrodes with the protective layer.

18. An Organic Light Emitting Diode (OLED) display with a plurality of pixels, each pixel comprising:
a driving backplane;
a first electrode deposited on top of the driving backplane;
a plurality of pixel defining layer deposited on top of the driving backplane and adjacent to the first electrode to define subpixel regions;
a common layer deposited on top of the plurality of pixel defining layer and on top of the first electrode;
an OLED device deposited on top of the common layer and above the electrode; and
a second electrode deposited on top of the OLED device, the second electrode having a protective layer.

19. The OLED display of claim 18, wherein the common layer further comprises a Hole Injection Layer (HIL).

20. The OLED display of claim 18, wherein the common layer further comprises a Hole Transport Layer (HTL).

21. A method for making a subpixel display for an Organic Light Emitting Diode (OLED) display on a driving backplane comprising the steps of:
depositing a plurality of first electrodes on top of the driving plane, the plurality of first electrodes being spaced apart;
depositing a light emitting layer of selected colors on top of the plurality of first electrodes and over an entire area of the driving backplane;
depositing a plurality of second electrodes on top of the light emitting layer, the plurality of second electrodes being covered by a protection layer; and
removing the light emitting layer and the second electrodes not deposited on top of the plurality of first electrodes, at the non-subpixel regions.

22. The method of claim 21, wherein the step of depositing the plurality of second electrodes forms a plurality of gaps exposing photo resist layers .

23. The method of claim 22, wherein the step of removing the light emitting layer and the second electrodes not deposited on top of the plurality of first electrodes at non-subpixel regions further comprises dissolving exposed materials of the photo resist layer with the selected chemicals.
